(19) United States
(12) Patent Application Publication
(10) Pub. No.: US 2026/0235652 A1
(43) Pub. Date: Aug. 13, 2026

(54) APPARATUS AND METHOD FOR MONITORING MOBILE GROUNDING DEVICES

(71) Applicant: Illinois Tool Works Inc., Glenview, IL (US)

(72) Inventors: Jan BARTH, Freudenstadt (DE); Walter SCHWARZWÄLDER, Maulberg (DE)

(21) Appl. No.: 19/156,642

(22) PCT Filed: Feb. 22, 2024
(86) PCT No.: PCT/US2024/016930

§ 371 Date: Aug. 14, 2025

(30) Foreign Application Priority Data
Mar. 3, 2023 (DE) 10 2023 105 307.8

(51) Int. Cl. G01R 27/20; G01R 27/18; G01R 31/52

(52) U.S. Cl. CPC G01R 27/205; G01R 27/18; G01R 31/52

(57) ABSTRACT

The present invention relates to an apparatus (202) as well as a method for monitoring mobile grounding devices (102), wherein the apparatus (202) comprises the following: a first pole (204) for connecting to a mobile grounding device (102); a second pole (206) for connecting a reference probe (208); and a control device. The control device is configured so as to sense an electrical resistance between the first pole and the second pole (204, 206) and compare it with a threshold. The control device outputs a status signal based on the comparison between the electrical resistance and the threshold.

### RELATED APPLICATIONS

This international application claims priority to German Patent Application No. 102023105307.8, filed Mar. 3, 2024. The entirety of German Patent Application No. 102023105307.8 is incorporated herein by reference.

### TECHNICAL FIELD

The present disclosure relates to an apparatus and a method for monitoring mobile grounding devices.

### BACKGROUND

When decanting, draining, pumping, mixing, spraying, measuring, sampling, or cleaning liquids, granules, or powders, the associated containers or substances themselves can electrically charge. The amount of charge depends on a few factors, for example the working methods, the properties and flow rates of the materials to be processed, and the size, geometry, and material of the containers.

### SUMMARY

Apparatus and methods for monitoring mobile grounding devices are disclosed, substantially as illustrated by and described in connection with at least one of the figures, as set forth more completely in the claims.

### BRIEF DESCRIPTION OF THE DRAWINGS

The examples of the disclosure are described in further detail below with reference to the drawings. The following are shown:

FIG. 1 a schematic illustration of a mobile grounding device according to the prior art;

FIG. 2 a schematic illustration of a grounding device with an apparatus for monitoring the mobile grounding device according to one embodiment of the present disclosure.

### DETAILED DESCRIPTION

As a result of the charging of containers and/or fillers described above, undesirable, uncontrolled discharges can occur during decanting and topping-up, which can lead to a variety of problems. On the one hand, the discharge can prevent the decanting or topping-up process. However, there are also more serious consequences: electrical devices connected to the containers (e.g., electrical scales) can be damaged. Finally, the uncontrolled discharge can also result in fires, particularly during the processing of highly flammable materials.

To counteract such a problem, it is known to use grounding systems that ensure a safe grounding and a controlled discharge of the containers associated therewith.

In addition to the aforementioned protection of systems, the grounding is also used in order to protect persons, in particular from leakage of fault currents, lightning impacts, static discharges, and electromagnetic interference. This is also referred to as protective grounding. Particularly when using mobile devices, for example emergency power packs, in the outdoors, it is often required that they be connected to an equipotential bonding/protective grounding. By contrast to the use of similar devices in buildings or other immobile facilities, there are usually no bindingly tested earth conductors or equipotential bonding conductors. In that case, the grounding/equipotential bonding must be established by mobile grounding points.

The mobile devices described above are often used by, for example, fire departments/disaster management teams. To ensure sufficient grounding, mobile grounding points, such as grounding stakes, are introduced locally into the existing ground by the first aid personnel. For this purpose, the grounding stakes can be hammered or twisted, for example. In this context, there is little time, especially in case of emergency missions, to introduce the grounding points into the ground or even check them for reliable grounding. If suitable measuring devices and time are available, only a random sample-like measurement is carried out.

Sufficient grounding by means of mobile grounding points is dependent on many factors. For example, the conductivity of mobile grounding devices is not only dependent on how reliably the grounding devices are secured in the earth. Rather, the composition of the ground also plays a major role. Thus, the conductivity of dry ground is less than that of wet ground. Also, it is not always directly obvious to the user what the ground is made of when the mobile grounding devices are hammered in. For example, a gravel bed located in the subsurface can reduce the conductivity, without this becoming known to the user.

Based on the aforementioned situation, the present disclosure addresses the problem of specifying an apparatus and a method for monitoring mobile grounding devices, with which the conductivity of mobile grounding devices can be determined quickly and reliably. The apparatus according to the disclosure is intended to be mobile and can readily be used on site together with the known mobile grounding devices.

This aforementioned problem is solved according to the disclosure by the subject matter of the independent claims 1 and 12. Further developments of the apparatus according to the disclosure or the method according to the disclosure for monitoring mobile grounding devices can be found in the dependent claims.

Accordingly, the present disclosure relates to an apparatus as well as a method for monitoring mobile grounding devices, wherein the apparatus comprises the following: a first pole for connecting to a mobile grounding device; a second pole for connecting a reference probe; a control device, wherein the control device is configured for the following purposes: sensing an electrical resistance between the first pole and the second pole; comparing the electrical resistance to a threshold; and outputting a status signal based on the comparison between the electrical resistance and the threshold.

The present disclosure is based on the finding that the conductivity of a grounding device is directly proportional to the resistance of the earth between the grounding device and a reference probe. For this purpose, in addition to the mobile grounding device, for example a grounding stake, a reference probe is also introduced into the ground. The reference probe can also be a grounding stake. The grounding stakes of the grounding device and the reference probe can be identical or can also be designed differently in terms of their dimensions. It should be noted that the resistance measured by the apparatus according to the disclosure corresponds to the leakage resistance of the “poorer” (e.g., smaller) grounding stake.

The two poles of the apparatus for monitoring mobile grounding devices can be connected to the mobile grounding device on the one hand and to the reference probe on the other hand in order to determine an electrical resistance between the two grounding stakes, that is to say between the mobile grounding device and the reference probe. In ideal starting conditions, it can be assumed that the resistance between the reference probe and the mobile grounding device substantially corresponds to the leakage resistance into the earth. As long as the electrical resistance sensed in this way lies below the threshold value, then the control unit outputs a grounding success signal through the apparatus, which can be used in order to inform the user that the conductivity is proper and the work can be started. If the electrical resistance sensed in this way exceeds the threshold value, then a warning signal is output by the apparatus, which can be used in order to inform the user that the conductivity is insufficient and that there is thus a possible injury/burn hazard. For example, the apparatus can be associated with an optical status indicator for indicating the status signal. In response to the grounding success signal, the visual status indicator can illuminate (e.g., green). In response to the warning signal, a lamp of the visual status indicator can go out or can also appear in a different color (e.g., red). The user can then attempt to readjust the mobile grounding device in order to achieve a sufficient conductivity and thus bring the resistance between the reference probe and the mobile grounding device below the threshold value.

According to a further embodiment, the control device is configured so as to sense the electrical resistance between the first pole and the second pole continuously or in regular intervals. Accordingly, the apparatus not only ensures that the conductivity of the mobile grounding device is sufficient during introduction, but also ensures the safety of the users throughout the entire use. For example, the control device can be configured so as to emit measurement signals at predetermined intervals in order to sense the electrical resistance between the two poles. Alternatively, the resistance measurement can be continuous. It can also be provided accordingly that the apparatus for monitoring the mobile grounding device provides the user with ongoing feedback about the conductivity of the grounding device. This allows the apparatus to provide positive feedback until the threshold is exceeded. The user can thereby exclude the possibility that a warning signal is not generated merely due to a failure of the apparatus.

According to a further embodiment, the apparatus comprises warning means for optical and/or audible output of the first warning signal. For example, the warning means can be lighting means, such as LEDs, that visually convey to the user that the threshold has been exceeded. Accordingly, the lighting means can illuminate red when the threshold value is exceeded. Until the threshold value is exceeded, the lighting means can be green, for example. Of course, any other combination of colors is possible, as well. In one design variant, if the threshold value is exceeded, the lighting means is switched off, i.e., the green light is switched off in order to alert the user. Alternatively, the apparatus of the present disclosure can comprise a speaker that emits warning sounds once the first warning signal is output by the control device. Of course, this has the advantage that the user need not be in the line of sight of the apparatus in order to perceive the first warning signal.

According to a further embodiment, the threshold value is less than the maximum normative requirement of the specific application. Accordingly, the control device can be configured so as to: receive application data indicative of the application of the mobile grounding device; and set the threshold based on the application data.

In this context, it is noted that different leakage resistances are acceptable under different application conditions. For example, in the controlled discharge of surface charges, it can be sufficient to achieve a leakage resistance of about 10 kOhm. By contrast, it can be necessary to achieve leakage resistances below 10 Ohms or even below 0.5 Ohms for protective grounding, for example of generators. However, it should be noted that these leakage resistances are only exemplary values that are not limiting for the disclosure. Rather, the control device is configured so as to detect the application case based on application data (e.g., an input from the user or an automatic detection of a connected object/device) and to adjust the threshold value accordingly. Thus, the control device can generally set a higher threshold value when the mobile grounding device is to be used in order to discharge surface charge and set a lower threshold value when the mobile grounding device is to be used for protective grounding. The respective thresholds per application case can be default settings of the device, which can be individually set in embodiments explained in further detail below.

According to a further embodiment, the apparatus is battery-operated or connected to an external power supply, wherein the control device can be configured so as to apply an intrinsically safe voltage to a pole for sensing the resistance. The term “intrinsically safe” refers to protection against explosions. There is no intrinsically safe voltage, per se, and also no intrinsically safe current, rather only the product of the two can be intrinsically safe. In other words, the control device can control the measurement voltage such that the voltage and current product does not exceed a maximum power. The measurement voltage controlled in this way can be referred to as “intrinsically safe.” The apparatus of the present disclosure not only operates in the 230 V range, but also provides reliable measurement results even in the 4.5 to 12 V range. Accordingly, the apparatus is easily transportable and can be used essentially in any location.

According to a further embodiment, the control apparatus comprises a control terminal which is connectable to a device to be grounded, wherein the control device is configured so as to output a release signal to the control terminal when the electrical resistance lies below the threshold and/or to output an emergency stop signal to the control terminal when the threshold is exceeded. In other words, according to this design variant, a control signal can be generated by the control device as soon as the threshold value is exceeded, alternatively or in addition to the status signal. The emergency shutdown signal can be sent via the control port to a device to be grounded, such as an emergency power pack, in order to switch it off as soon as the threshold is exceeded. Accordingly, the apparatus according to this embodiment does not depend on the attention or response time of the user. Rather, the apparatus can automatically ensure that the mobile devices connected thereto can only be operated when a reliable conductivity is ensured. Alternatively or additionally, the control device can provide a release signal for operating the device to be grounded as long as the electrical resistance lies below the threshold value.

According to a further embodiment, the control device is configured so as to: receive grounding device data indicative of a used grounding device; set the threshold based on the grounding device data.

According to this embodiment, the apparatus of the present disclosure can be configured based on the application case. For example, the grounding device data can be entered by the user. For this purpose, the apparatus can be equipped with a corresponding interface, such as a touch screen, via which the user can, for example, enter the model number of the grounding device.

According to a further embodiment, the grounding device data comprises one or more of the following parameters: a type of the grounding device; a length of the grounding device; a diameter of the grounding device; and/or a material of the grounding device.

It has been found that the resistance between the poles as determined by the apparatus depends on the type and design of the grounding device. It is relevant, for example, whether it is a grounding device for hammering or screwing, or even grounding belts. The length and diameter of the grounding devices that can be lowered into the earth can also have an influence on the resistance. Thus, it is generally assumed that a deeper penetration of the grounding device into the earth results in lower resistance values. Accordingly, the control device of the present disclosure can be configured so as to correct the first threshold value downward when using longer grounding devices.

According to a further embodiment, the reference probe (208) and the grounding device (102) consist of materials that are as close together in the galvanic voltage series such that a generated galvanic voltage does not exceed a maximum proportion of the metering voltage applied by the apparatus (202) to the poles, depending on the application. In other words, the materials are chosen according to this embodiment such that the galvanic voltage always lies below the measurement voltage. The maximum proportion of the applied measurement voltage that is acceptable for the galvanic voltage depends on the application. For example, the galvanic voltage for the release of electrostatic derivatives must not be more than 40% of the measurement voltage. For the release of low-ohmic compounds, e.g., 10 Ohm, the galvanic voltage must not exceed 10% of the measured voltage.

According to a further aspect, the present disclosure relates to a mobile grounding system comprising the following: one of the aforementioned apparatuses for monitoring mobile grounding devices; a grounding device that is or can be connected to the first pole of the apparatus; and a reference probe that is or can be connected to the second pole of the apparatus.

According to a further aspect, the present disclosure relates to a method for monitoring mobile grounding devices, wherein the method comprises the following: inserting a mobile grounding device, in particular a grounding stake, into the ground; inserting a reference probe, in particular a grounding stake, into the ground; measuring an electrical resistance between the mobile grounding device and the reference probe; comparing the electrical resistance to a threshold; and outputting a status signal based on the comparison between the electrical resistance and the threshold.

According to a further embodiment, the grounding device is distanced at least 0.5 m from the reference probe. It has been found that particularly reliable resistance values can be sensed by the control unit with the minimum distance of 0.5 m.

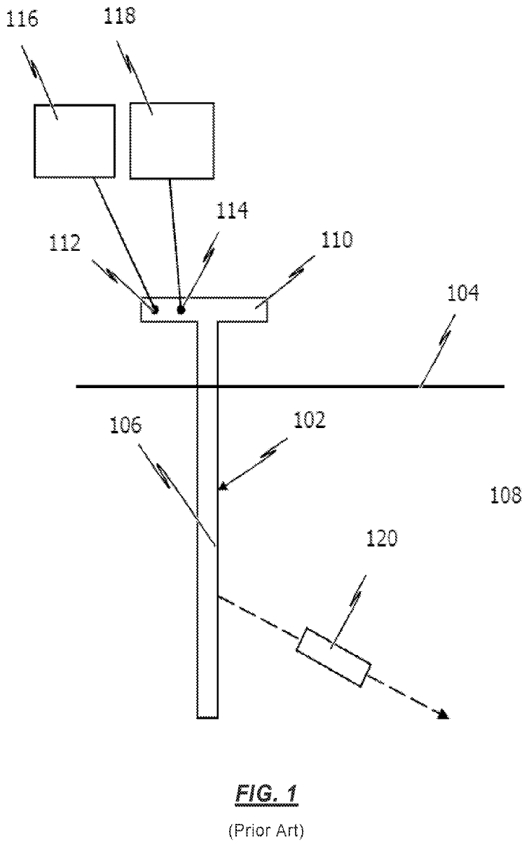

FIG. 1 shows a grounding device 100 for grounding mobile devices and charge carriers. The mobile grounding device 100 known in the prior art substantially comprises a grounding stake 102, which, during each application, is first rotated into the ground 104 by the user. The grounding stake 102 comprises an elongated part 106, which can be introduced into the ground 104 and thus into the underlying earth 108. For this purpose, it can be hammered or twisted into the earth 108. However, it should be noted at this point that the present disclosure is not limited in terms of the type of mobile grounding device. Rather, other grounding devices than the grounding stake shown here, such as grounding belts, can also be used. In any case, they serve to connect a mobile terminal device or charge carrier to the earth 108.

In addition to the elongated portion 106, the grounding stake 102 shown by way of example in FIG. 1 has an interface region 110 that is introduced into the earth 108. The interface region 110 serves in particular for connecting the devices or charge carriers to be grounded. For example, in FIG. 1, the mobile grounding device comprises two ports 112, 114. A first port 112 is connected to a first object/device 116 to be discharged, while the second port 114 is connected to a second device 118 to be grounded. The mobile grounding device 102 can thus be used in order to ground a large variety of surfaces/devices.

The electrical connection between the elongated portion 106 of the grounding device 102 and the earth 108 is typically not completely resistance-free. Rather, there is always some leakage resistance 120 between the mobile grounding device 102 and the earth 108, which is shown schematically in FIG. 1. The leakage resistance depends on several factors. For example, on the one hand, the nature of the earth 108 and, on the other hand, the characteristics of the mobile grounding device 102 are critical. In particular, the penetration depth of the mobile grounding device 102 can play a major role. It has also been found that the diameter of the elongated region 106 which is introduced into the earth 108 also has an influence on the leakage resistance 120.

The leakage resistance 120 is generally to be kept as low as possible in order to achieve a reliable grounding of the surfaces/devices in question. However, in the mobile grounding devices known from the prior art, one must often simply trust that the leakage resistance 120 is low enough to ensure reliable grounding. However, this can lead to complications, especially in dry substrates, such as gravel.

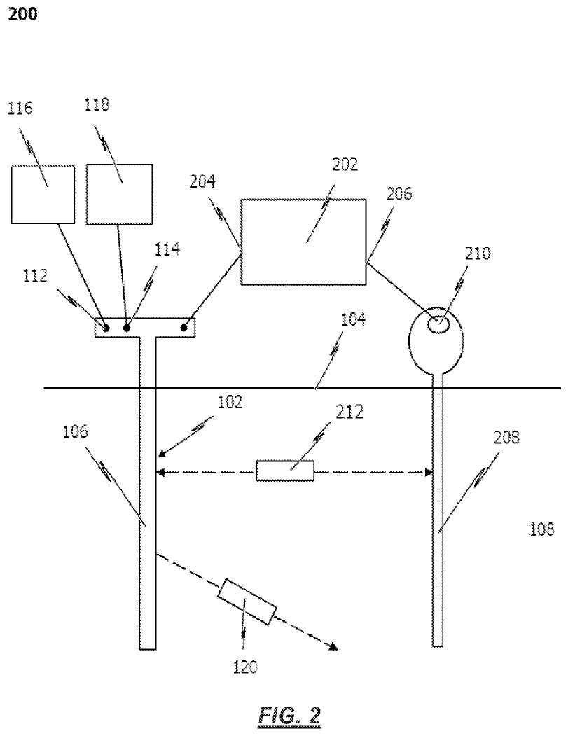

The present disclosure relates to an apparatus for monitoring mobile grounding devices, as shown schematically in FIG. 2. In particular, the apparatus according to the disclosure can be used for permanent, i.e., continuous or regular, monitoring of the grounding quality. In particular, FIG. 2 provides a schematic illustration of a system made of a mobile grounding device as well as an apparatus for monitoring the mobile grounding device. The system 200 seen in FIG. 2 comprises a grounding device 102, which in this example is identical to the grounding device already shown in FIG. 1.

The apparatus 202 for monitoring the grounding device 102 comprises a first pole 204, which is electrically connectable to the mobile grounding device 102. The first pole 104 is in particular connected to the interface region 110 of the grounding device 102. In other words, the apparatus 202 is connected to the earth 108 via the grounding device 102.

The apparatus 202 further comprises a second pole 206 connected to the earth 108 at a location that is distanced from the mobile grounding device 102. In the exemplary embodiment shown here, the system includes a reference probe 208 that is introduced into the ground 106 at a distance from the mobile grounding device and thus electrically connected to the earth 108. The reference probe 208 can also be a grounding stake, for example. However, the reference probe 208 is shown slightly differently in FIG. 2 in order to highlight the difference between the mobile grounding device 102 and the reference probe 208. It should be noted, however, that the reference probe 208 serves only to connect the second pole 206 to the earth 108. A grounding via the reference probe 208 is preferably not provided, although this would be technically equivalent and accordingly conceivable. In other words, in advantageous embodiments, the reference probe 208 only has one port 210, which is configured so as to electrically connect the reference probe 208 to the apparatus 202 for monitoring the grounding device 102.

Preferably, the reference probe 208 is hammered as deep into the earth 108 as the mobile grounding device 102. It should be noted that the measured resistance value generally corresponds to the “poorer” leakage resistance between the reference probe 208 and the grounding device 102. Thus, if the reference probe 208 causes a significantly greater resistance than is the case for the grounding device 102, then the measurement result and thus the status signal is distorted, because it is conceivable that the grounding device may be sufficiently grounded, but only the reference probe 208 provided for monitoring has an inadequate connection to the ground. In this case, the control apparatus [sic: device] can output a warning signal, although the leakage resistance via the grounding device 102 would be generally acceptable, i.e., would fall below the necessary threshold. For the aforementioned reasons, the reference probe 208 is preferably hammered equally deep or even deeper into the earth 108 than the grounding stake of the grounding device. For this purpose, the grounding device 102 and the reference probe 208 can be equipped with corresponding markings in order to ensure that the reference probe 108 and the grounding device are hammered/screwed sufficiently deep into the ground.

The reference probe 208 is preferably at least 0.5 m away from the grounding device 102. Accordingly, the system 200 can comprise an apparatus (not shown) for distancing the grounding device 102 from the reference probe 208. For example, the apparatus can be a flexible plastic sheet (e.g., made of composite material, such as a ski) that not only distances the reference probe 208 from the grounding device 102, but also insulates them from one another.

The apparatus 202 for monitoring the mobile grounding device 102 comprises a control device for sensing an electrical resistance between the first and second poles 204, 206. In the illustrated embodiment according to FIG. 2, the resistance between the two poles 204, 206 of the apparatus 202 corresponds to the total resistance of the circuit formed by the mobile grounding device 102, the earth 108, and the reference probe 208. Because the mobile grounding device and the reference probe are formed from metal, their electrical resistance to the earth is negligible. In other words, in the embodiment according to FIG. 2, the apparatus 202 only sees a resistance 212 of the earth 108 between the mobile grounding device 102 and the reference probe 208.

The present disclosure is based on the finding that the resistance 212 between the mobile grounding device 102 and the reference probe 208 substantially corresponds to the leakage resistance 120. Accordingly, based on the resistance 212 between the mobile grounding device 102 and the reference probe 208, a conclusion about the leakage resistance 120 and, accordingly, the reliable grounding can be made via the mobile grounding device 120.

The control device of the apparatus 202 for monitoring the mobile grounding device 102 is configured so as to compare the electrical resistance between the two poles 204, 206 to a threshold value (not shown). When the electrical resistance exceeds the threshold value, the control device generates a warning signal, which can be used, for example, in order to drive corresponding warning means for optical and/or audible feedback. The threshold value can be set/adjusted for different applications. Thus, much lower leakage resistances are usually needed in order to achieve a sufficient protective grounding (e.g., <10 Ohm) than would be necessary for the derivation of surface charges (e.g., <10 kOhm). Accordingly, the control device can be configured so as to change the threshold value based on user information regarding the specific application case (application data). The user information can be input via a corresponding interface, such as a touch screen. The control device can be configured so as to prompt the user for an indication of the application case (e.g., by drop-down) upon power-up.

In an exemplary embodiment, the status signal can be output to the user by lighting up a status lamp. Alternatively or additionally, a warning sound can be output by the apparatus for monitoring the mobile grounding device. In the normal state, for example, when the resistance between the two poles is below the threshold value, positive feedback can be output, for example, by a green light. As long as the resistance between the two poles 204, 206 lies below the threshold, the green status light will continue to be displayed. The status signal output by the control device is used in order to switch off the green status indicator only when the threshold value is exceeded. According to this embodiment, the user also already receives feedback during introduction when sufficient grounding is achieved, namely when the positive status signal (for example, green light) is output by the apparatus 202.

The present disclosure is not limited to the embodiments presented in the drawings, but rather results from a combination of all of the features disclosed herein.

1. An apparatus for monitoring mobile grounding devices, wherein the apparatus comprises:
a first pole for connecting to a mobile grounding device;
a second pole for connecting a reference probe;
a control device, wherein the control device is configured for the following purposes:
sensing an electrical resistance between the first pole and the second pole;
comparing the electrical resistance to a threshold;
outputting a status signal based on the comparison between the electrical resistance and the threshold.

2. The apparatus according to claim 1, wherein the control device is configured so as to sense the electrical resistance between the first pole and the second pole continuously or in regular intervals.

3. The apparatus according to claim 1, wherein the apparatus comprises means for optical and/or audible output of the status signal.

4. The apparatus according to claim 1, wherein the control device is configured so as to output a grounding success signal as a status signal when the electrical resistance lies below the threshold; and/or wherein the control device is configured so as to output a warning signal as a status signal when the electrical resistance lies above the threshold.

5. The apparatus according to claim 1, wherein the control device is configured to:
receive application data indicative of the application of the mobile grounding device; and
set the threshold based on the application data.

6. The apparatus according to claim 1, wherein at least one of the apparatus is battery-operated or connectable to an external power supply or the control device is configured so as to apply an intrinsically safe voltage to a pole for sensing the resistance.

7. The apparatus according to claim 1, wherein the apparatus comprises a control terminal which is connectable to a device to be grounded, and wherein the control device is configured to at least one of output a release signal to the control terminal when the electrical resistance lies below the threshold or output an emergency stop signal to the control terminal when the threshold is exceeded by the electrical resistance.

8. The apparatus according to claim 1, wherein the control device is configured to:
receive grounding device data indicative of a used grounding device; and
set the threshold based on the grounding device data.

9. The apparatus according to claim 8, wherein the grounding device data comprises one or more of the following parameters:
a type of the grounding device;
a length of the grounding device;
a diameter of the grounding device; or a material of the grounding device.

10. A mobile grounding system, comprising:
the apparatus according to claim 1;
a grounding device configured to be connected to the first pole of the apparatus; and
a reference probe configured to be connected to the second pole of the apparatus.

11. The mobile grounding system according to claim 10, wherein the grounding system comprises an apparatus for distancing the reference probe from the grounding device, which is configured such that the reference probe is distanced at least 0.5 m from the grounding device.

12. The mobile grounding system according to claim 10, wherein the reference probe and the grounding device consist of materials that are as close together in the galvanic voltage series such that a generated galvanic voltage does not exceed a maximum proportion of the metering voltage applied by the apparatus to the poles, the maximum proportion depending on the application.

13. A method for monitoring mobile grounding devices, wherein the method comprises:
inserting a mobile grounding device, in particular a grounding stake, into the ground;
inserting a reference probe, in particular a grounding stake, into the ground;
measuring an electrical resistance between the mobile grounding device and the reference probe;
comparing the electrical resistance to a threshold; and
outputting a status signal based on the comparison between the electrical resistance and the threshold.

14. The method according to claim 13, wherein the grounding device is distanced at least 0.5 m from the reference probe.
